(19) United States
(12) Patent Application Publication
(10) Pub. No.: US 2017/0328946 A1
(43) Pub. Date: Nov. 16, 2017

(54) METHOD FOR OPERATING A FAULT INDICATOR

(71) Applicant: SIEMENS AKTIENGESELLSCHAFT, MUNICH (DE)

(72) Inventors: WIEBKE FROEHNER, AMBERG (DE); THOMAS WERNER, REDNITZHEMBACH (DE)

(21) Appl. No.: 15/594,831

(22) Filed: May 15, 2017

(30) Foreign Application Priority Data
May 13, 2016 (EP) 16169534.1

(51) Int. Cl. G01R 31/08; H02H 7/26; G06F 17/30; G06N 3/02; G06Q 50/06

(52) U.S. Cl. CPC G01R 31/088; G06F 17/30041; H02H 7/263; G01R 31/085; G06F 17/30044; G06Q 50/06; G06N 3/02

(57) ABSTRACT

A method operates a fault indicator, in particular a fault current indicator, which can detect a fault in an electrical energy transmission line, in particular a fault current in the energy transmission line. In the event of a detected fault, the fault indicator transmits a fault signal to a superordinate control center monitoring the energy transmission line. The fault indicator regularly or irregularly transmits at least one item of local weather information, which relates to the weather in the environment of the fault indicator, to the superordinate control center, directly to a central device other than the control center or indirectly to the other central device via the control center.

### CROSS-REFERENCE TO RELATED APPLICATION

This application claims the priority, under 35 U.S.C. §119, of European application EP 16169534.1, filed May 13, 2016; the prior application is herewith incorporated by reference in its entirety.

### BACKGROUND OF THE INVENTION

### Field of the Invention

The invention relates, inter alia, to a method for operating a fault indicator, in particular a fault current indicator, which can detect a fault in an electrical energy transmission line, in particular a fault current in the energy transmission line, and, in the event of a detected fault, transmits a fault signal to a superordinate control center monitoring the energy transmission line.

It is known that fault indicators (also called fault passage indicator) can be used to detect faults in medium-voltage overhead lines, which fault indicators monitor the magnetic field of the line with inductive coupling and trigger a signal if a fault current passes through (for example in the event of a ground fault or a short circuit). The first fault indicators of this type were already being used at the end of the 1940s. Although these fault indicators were inexpensive to acquire, they locally provide only an optical signal in the event of a fault. If a fault occurs, the line course must be combed by maintenance teams during the search for the fault until the fault location has been found. In order to avoid such combing, fault indicators which are equipped with their own communication module, in particular in the form of their own gateway, and transmit their information to a central control system, referred to here as a control center below, have also been used for some years.

However, the newly used fault indicators with communication capabilities are considerably more expensive, in terms of acquisition and operation, than the previously used fault indicators without communication capabilities; for this reason, fault indicators with communication capabilities are generally currently usually installed only at selected, generally poorly accessible, locations in the energy transmission network.

### SUMMARY OF THE INVENTION

The invention is based on the object of specifying a method for operating fault indicators which makes their use more attractive than before.

Accordingly, the invention provides for the fault indicator to regularly or irregularly transmit at least one item of local weather information, which relates to the weather in the environment of the fault indicator, to the superordinate control center, directly to a central device other than the control center or indirectly to the other central device via the control center.

An important advantage of the method according to the invention can be seen in the fact that the fault indicators are used not only to generate and forward fault signals but also to forward local weather information. The infrastructure needed to operate the fault indicators can therefore be used twice in the method according to the invention, namely to transmit the fault signals, on the one hand, and to transmit the local weather information, on the other hand.

In order to be able to continue to operate the existing infrastructure with as minimal adaptation effort as possible, it is considered to be advantageous if the at least one item of local weather information is transmitted using the same communication protocol and on the same communication channel as the fault signals in the event of a fault.

With regard to central further processing of the weather information, it is considered to be advantageous if the at least one item of local weather information is transmitted to a central device in the form of a central cloud system.

With regard to the handling of the local weather information in the cloud, it is considered to be advantageous if the information is stored in a database of the central cloud system and/or is visualized—alone or with other weather information, in particular weather information from other sources—using visualization means of the central cloud system.

In addition, it is advantageously possible to use the local weather information, alone or together with weather information from other sources, to create a weather forecast and to create a weather forecast which, with respect to the environment of the fault indicator, is locally more established, in a manner based on measured values, than a weather forecast without the additional local weather information from the fault indicator.

In addition, the local weather information can be processed further during a forecast improvement method, in which a locally modified weather forecast is created on the basis of a previously created global or regional weather forecast taking into account the local weather information.

The weather forecast created using the local weather information or the locally modified weather forecast can be advantageously used to control the supply of energy into an energy transmission network. For example, the local weather information can be used to control the supply of energy into that energy transmission network which is also monitored with the fault indicator for faults, in particular fault currents.

Alternatively or additionally, the local weather information used to control heating systems.

A forecast method for forming a weather forecast on the basis of the local weather information and/or a forecast improvement method can be advantageously carried out using an artificial neural network, for example based on a multilayer perceptron model or statistical methods such as the support vector machines.

If an artificial neural network is used, it is considered to be advantageous if a network having at least three layers is used, the input layer and the output layer of the layers of the network each having the same number of perceptrons. Each perceptron respectively represents in this case a variable of the weather forecast for each interval of time.

During a forecast improvement method, a previously created global or regional weather forecast and the local weather data from the fault indicators can be input to the input layer, for example, by applying the corresponding weather data to the perceptrons of the input layer. The locally modified weather forecast determined by the neural network is output by means of the perceptrons of the output layer.

Before the forecast method or the forecast improvement method is carried out, the artificial neural network is preferably trained with the aid of the back propagation method and measured weather data as training data.

The fault indicator or at least its communication module (for example gateway) is preferably operated with solar energy obtained by use of a solar cell of the fault indicator. It is also advantageous if the respective power output of the solar cell is used as a measure of the respective solar radiation and a measured solar radiation value is generated on the basis of the respective power output. The measured solar radiation value is preferably transmitted as the at least one item of local weather information or one of the items of local weather information to the control center and/or the central device.

The fault indicator can also have one or more further weather sensors, in particular a rain gage, a wind gage, a temperature sensor and/or an air pressure sensor, the sensor signals of which are transmitted as local weather information to the control center and/or the central device.

Another advantageous configuration provides for the fault indicator to comprise, in addition to a communication module, in particular a gateway, which is suitable for transmitting the fault signal to the control center, an additional communication device, in particular a near field communication device.

A data connection, in particular in the form of a radio connection, is preferably maintained between at least one current and/or voltage sensor of the fault indicator and the communication module of the fault indicator by means of such an additional communication device in order to transmit the measured values from the current and/or voltage sensor and/or a fault signal already formed therefrom in the sensor to the communication module or gateway for the purpose of forwarding to the control center.

Alternatively or additionally, a data connection, in particular in the form of a radio connection, can be maintained between at least one external weather sensor and the communication module of the fault indicator by such an additional communication device in order to transmit weather information from the external weather sensor to the communication module or gateway for the purpose of forwarding to the control center.

In other words, provision may therefore be made for the fault indicator to permanently or at least occasionally, in particular regularly or irregularly, have a communication connection to one or more external weather sensors by the communication device, for the sensor signals from the external weather sensors to be transmitted to the fault indicator via the communication connection, and for the sensor signals to then be forwarded from the communication module or gateway of the fault indicator as local weather information to the control center and/or the central device.

For the purpose of monitoring an energy transmission network, in addition to the at least one fault indicator, further fault indicators are preferably operated, which further fault indicators each monitor the same electrical energy transmission line as the fault indicator or monitor a different electrical energy transmission line of the same energy transmission network which is indirectly or directly connected to the energy transmission line and, in the event of a fault, each transmit a fault signal to the superordinate control center by their communication module. Each of the fault indicators preferably respectively regularly or irregularly also transmits at least one item of local weather information, which relates to the weather in the environment of the respective fault indicator, to the control center or directly to a central device or indirectly to a central device via the control center using its communication module. The local weather information is preferably transmitted in each case using the same communication protocol and on the same communication channel as that used to transmit the fault signals. If one or more fault signals are received, the control center determines those sections of the energy transmission network which are affected by the fault on the basis of the fault signals.

The local weather information from the fault indicators is preferably stored in a database of a central cloud system, and/or visualized, and/or used to create a weather forecast, and/or used to create a locally modified weather forecast, for example on the basis of a previously created global or regional weather forecast and on the basis of the local weather information provided by the fault indicators.

The invention also relates to a fault indicator for detecting a fault in an electrical energy transmission line, in particular a fault current in the energy transmission line, and for transmitting a fault signal to a superordinate control center monitoring the energy transmission line in the event of a detected fault.

With respect to such a fault indicator, the invention provides for the fault indicator to be configured in such a manner that it regularly or irregularly transmits at least one item of local weather information, which relates to the weather in the environment of the fault indicator, to the superordinate control center, directly to a central device other than the control center or indirectly to the central device via the control center using a communication module.

With respect to the advantages of the fault indicator according to the invention, reference is made to the above statements in connection with the method according to the invention.

With regard to the configuration of the fault indicator, it is considered to be advantageous if the fault indicator has one or more weather sensors, the sensor signals of which are transmitted as local weather information to the control center and/or the central device.

Alternatively or additionally, the fault indicator can be configured in such a manner that it can permanently or occasionally have a communication connection to one or more external weather sensors and forwards received sensor signals from the external weather sensors to the control center and/or the central device as local weather information using its communication module.

The invention also relates to a monitoring device for monitoring an energy transmission network, having a multiplicity of fault indicators which monitor electrical energy transmission lines of an energy transmission network and, in the event of a fault, each transmit a fault signal to a superordinate control center of the monitoring device using a communication module.

With regard to the configuration of the monitoring device, the invention provides for the fault indicators to be configured as explained above.

Other features which are considered as characteristic for the invention are set forth in the appended claims.

Although the invention is illustrated and described herein as embodied in a method for operating a fault indicator, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is an illustration showing an exemplary embodiment of a monitoring device which can be used to monitor an energy transmission network according to the invention;

FIG. 2 is an illustration showing an exemplary embodiment of a fault indicator which can be used in the monitoring device according to FIG. 1;

FIG. 3 is an illustration showing another exemplary embodiment of the fault indicator which can be used in the monitoring device according to FIG. 1;

FIG. 4 is an illustration showing an exemplary embodiment of a central cloud system which can be connected to the monitoring device according to FIG. 1; and

FIG. 5 is an illustration showing an exemplary embodiment of a neural network which can be used to create a weather forecast or to locally improve or make a global or regional weather forecast more precise.

### DETAILED DESCRIPTION OF THE INVENTION

In the figures, the same reference symbols are always used for identical or comparable components for the sake of clarity.

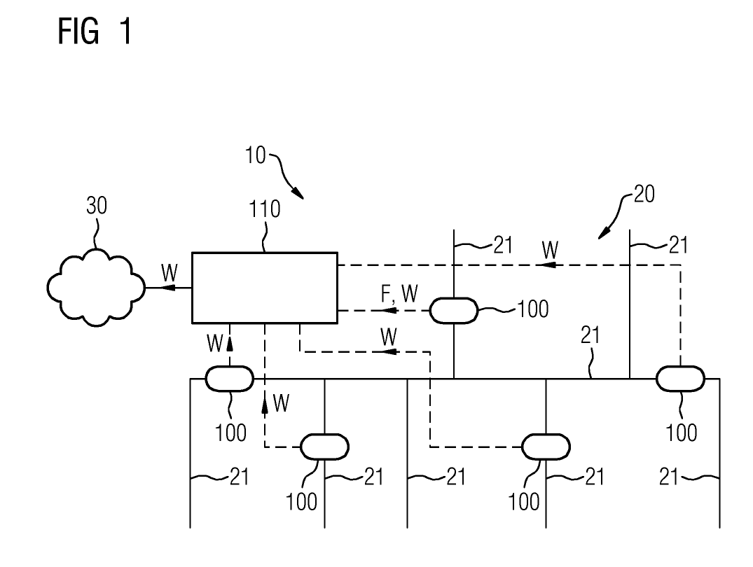

Referring now to the figures of the drawings in detail and first, particularly to FIG. 1 thereof, there is shown a monitoring device 10 which is used to monitor an energy transmission network 20. The energy transmission network 20 is formed by a multiplicity of energy transmission lines 21 which are connected to one another.

The monitoring device 10 contains a multiplicity of fault indicators 100 which are each assigned to one of the energy transmission lines 21 and are each connected to a control center 110 of the monitoring device 10. In the event of a fault, those fault indicators 100 which detect a fault generate a fault signal F and transmit it to the control center 110. The control center 110 can locate the fault location inside the energy transmission network 20 on the basis of the incoming fault signals F and can separate the faulty section of the energy transmission network 20 from the remaining energy transmission network 20 possibly by disconnecting individual energy transmission lines 21.

The fault indicators 100 are also configured in such a manner that they permanently or at least occasionally, be it regularly or irregularly, generate local weather information W and transmit it to the control center 110. The local weather information W is preferably transmitted by the fault indicators 100 in exactly the same manner as the fault signals F in the event of a fault, that is to say preferably on the same communication channel and using the same communication protocol as the fault signals F.

The local weather information W is preferably transmitted in the form of measured values or measured value signals, for example measured temperature values, measured pressure values, measured precipitation values, measured wind values, etc.

In the exemplary embodiment according to FIG. 1, the control center 110 forwards the weather information W to a central device in the form of a central cloud system 30. The local weather information W can be stored in the central cloud system 30 and/or can be visualized using visualization means of the central cloud system 30. It is also possible to create a weather forecast in the central cloud system 30 on the basis of the local weather information W or to locally refine an already created global or regional weather forecast on the basis of the local weather information W or to make it more precise.

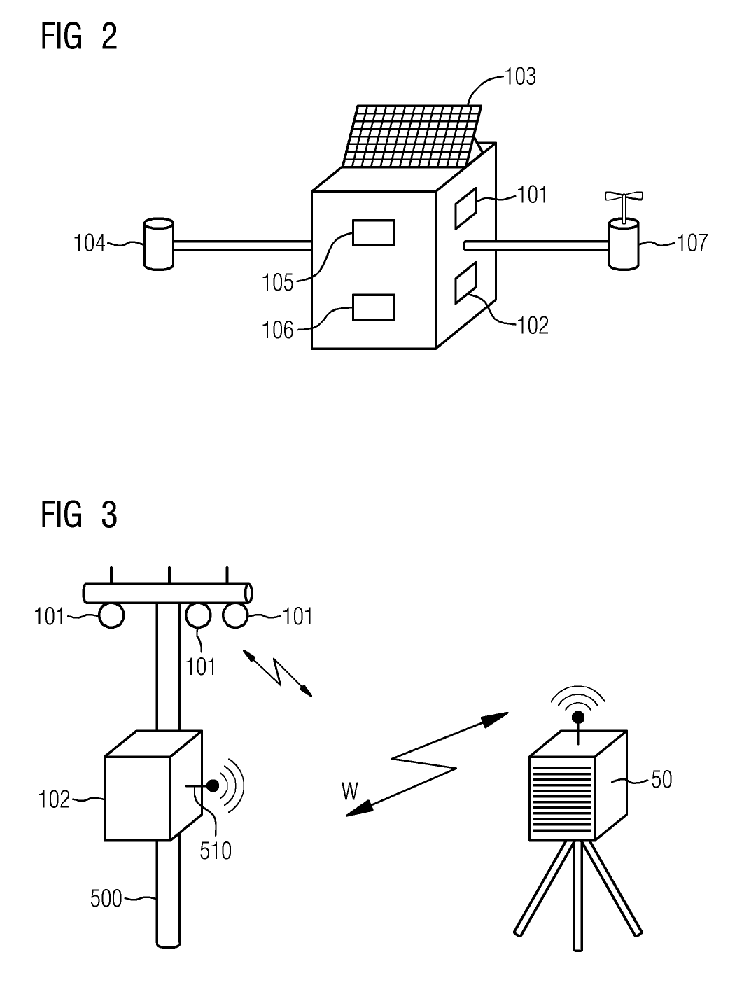

FIG. 2 shows an exemplary embodiment of a fault current indicator which can be used as a fault indicator 100 in the transmission device 10 according to FIG. 1. The fault current indicator contains current sensors 100 which can be used to measure the current through the energy transmission line 21 according to FIG. 1 which is monitored by the fault current indicator; faults, for example ground faults or short circuits in particular, can be detected on the basis of the measurement results and a fault signal F can be generated if necessary.

The current sensors 100 of the fault current indicator are connected to the fault indicator's own communication module in the form of a gateway 102 which makes it possible to transmit the fault signal F to the control center 110 according to FIG. 1, for example in a wired manner or by radio.

For the power supply, the fault current indicator according to FIG. 2 is equipped with a solar cell 103. The respective power output of the solar cell 103 is used by the fault current indicator as a measure of the respective solar radiation and a measured solar radiation value is generated on the basis of the respective power output of the solar cell 103 and is transmitted as local weather information W to the control center 110 according to FIG. 1. The solar cell 103 is therefore used twice, namely as a generator and as a weather sensor.

The fault current indicator is also equipped with a multiplicity of further weather sensors, of which a rain gage 104, a temperature sensor 105, an air pressure sensor 106 and a wind gage 107 are illustrated, by way of example, in FIG. 2. The sensor signals of these weather sensors are transmitted as local weather information W to the control center 110 according to FIG. 1.

In the exemplary embodiment according to FIG. 2, the fault current indicator is therefore itself equipped with weather sensors, the sensor signals of which are forwarded as local weather information W.

FIG. 3 shows another exemplary embodiment of a fault current indicator which can be used as a fault indicator 100 in the energy transmission network 20 according to FIG. 1. In the case of the fault current indicator, current sensors 101 fastened to a mast 500 and the gateway 102 are arranged at a distance from one another and communicate with one another via a near field communication connection, for example Zigbee or the like. The sensor data from the current sensors 101 are transmitted, via the near field communication connection, to the gateway 102 which, in the event of a fault, transmits a fault signal F to the control center 110 according to FIG. 1. The sensor data from the current sensors 101 can be evaluated in the sensor or gateway for the purpose of detecting faults and generating fault signals.

In order to operate the near field communication connection, the fault current indicator has an additional communication device 510, here in the form of a near field communication device.

The gateway 102 is also connected, via a near field communication connection, to an external weather station 50 from which the gateway 102 receives external local weather data W. The external local weather data W are forwarded from the gateway 102 to the control center 110 according to FIG. 1.

In the exemplary embodiment according to FIG. 3, the gateway 102 of the fault current indicator therefore has a dual interface function since it forms both an interface to the current sensors 101 and an interface to the external weather station 50.

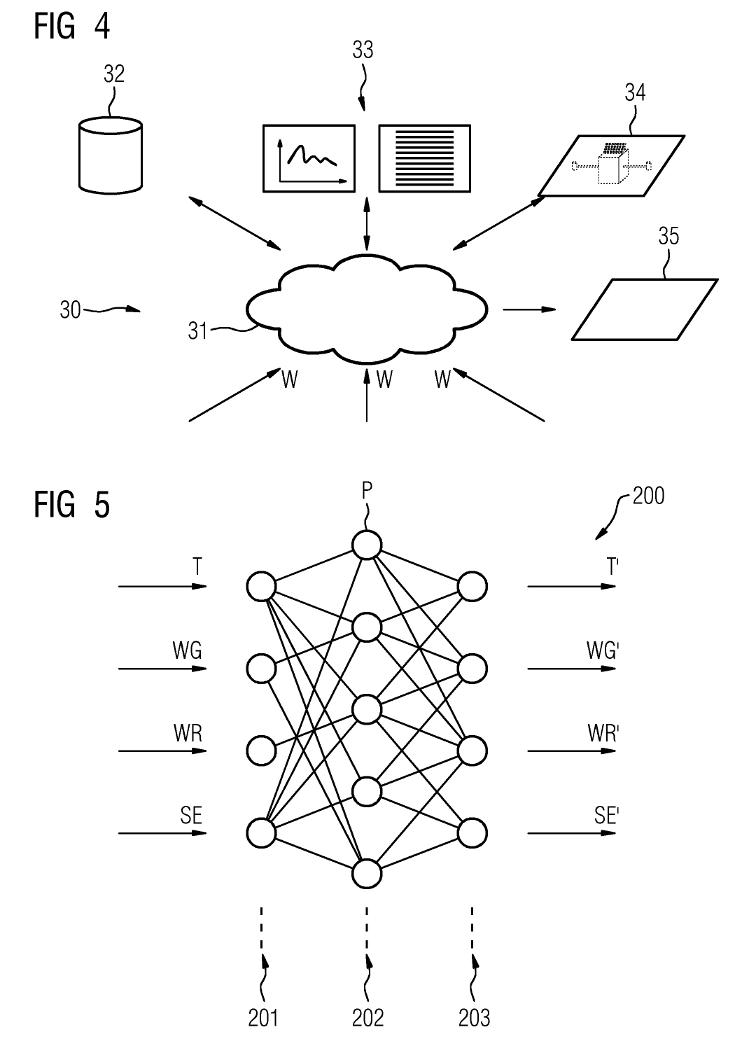

FIG. 4 shows an exemplary embodiment of a central cloud system 30 more specifically in detail. The central cloud system 30 has a cloud 31 to which the local weather information W from the fault indicators 100 according to FIG. 1 is supplied.

In the cloud, the central cloud system 30 preferably provides a database 32 for storing the local weather information W, visualization means 33 for visualizing the local weather information W, forecast means 34 for creating a weather forecast using the local weather information W and forecast adaptation means 35 for locally improving a regional or global weather forecast.

The database 32 can make it possible, for example, for third parties to access the local weather information via suitable interfaces so that said third parties can externally evaluate the data. For example, a weather forecast can be externally created or a created regional or global weather forecast can be externally refined using the local weather information W.

The visualization means 33 enable a geographically oriented representation of the weather information, for example. The positions of the fault indicators can be displayed on a map, for example. Windows in which the local weather information is presented can be opened by clicking on the positions.

FIG. 5 shows an exemplary embodiment of a neural network 200 which can be used to implement the forecast means 34 or the forecast adaptation means 35 according to FIG. 4.

In the exemplary embodiment according to FIG. 5, the neural network 200 contains three layers 201, 202 and 203. The input layer 201 and the output layer 203 of the neural network 200 preferably each have the same number of perceptrons P. Each perceptron P of the input layer 201 represents a variable of a global or regional weather forecast which has already been created for each interval of time. The output layer 203 or the perceptrons P of the output layer 203 is/are used to output the local weather forecast determined by the neural network 200 or to output the weather forecast locally adapted or locally modified by the neural network 200.

In the illustration according to FIG. 5, it is assumed, for example, for an interval of time that measured temperature values T forecast as part of a weather forecast created in another manner, wind speeds WG forecast as part of a weather forecast created in another manner, wind direction indications WR forecast as part of a weather forecast created in another manner, solar radiation values SE forecast as part of a weather forecast created in another manner are supplied to the input layer 201. The corresponding forecast values in the form of forecast measured temperature values or forecast measured temperature values T′ adapted by local weather information, forecast wind speeds or forecast wind speeds WG′ adapted by local weather information, forecast wind direction indications or forecast wind direction indications WR′ adapted by means of local weather information and forecast solar radiation values or forecast solar radiation values SE′ adapted by means of local weather information are output at the output layer 203.

The neural network 200 is preferably trained with the aid of the back propagation method and on the basis of measured weather data as training data.

In summary, the basic concept of the exemplary embodiments according to FIGS. 1 to 5 is that of using fault indicators, in particular fault current indicators, to record weather data in order to be able to provide cloud-based services using this information. These services may include, inter alia, the forwarding of the measured local weather data to weather services and the calculation of local weather forecasts.

Potential customers for the measured weather data may be national or private weather services, for example. The latter currently themselves still operate a complicated network of weather stations which must be provided with their own communication technology and accordingly must also be maintained.

In addition to the acquired local weather data, improved local weather forecasts can also be offered as services. Possible customers for these services are, for example, the operators of electrical distribution networks who take weather data into account in the operational management of their networks. These forecasts may be relevant, in particular, when it is necessary to intervene in the operation of the systems in a controlling manner on account of a lack of network capacities.

In addition, the operators of virtual power plants, whose portfolio contains regenerative decentralized production systems, may also be interested in an improved local weather forecast.

Another target group for the improved local weather forecasts mentioned above may also be the operators of heating systems. Heating systems are currently generally controlled on the basis of the current outside temperature in each case. A more pleasant indoor climate and lower heating costs can be achieved, however, if the heating power is controlled not only on the basis of the current outside temperature in each case but also on the basis of a locally accurate temperature forecast. It is also possible to control the heating power solely on the basis of a locally accurate temperature forecast, thus making it possible to dispense with individual outside temperature sensors.

In summary, the technical and economic benefit of fault indicators can be considerably improved by additionally generating and/or forwarding local weather information.

Although the invention was described and illustrated more specifically in detail by means of preferred exemplary embodiments, the invention is not restricted by the disclosed examples and other variations can be derived therefrom by a person skilled in the art without departing from the scope of protection of the invention.

The following is a summary list of reference numerals and the corresponding structure used in the above description of the invention:
10 Monitoring device
20 Energy transmission network
21 Energy transmission lines
30 Cloud system, central device
31 Cloud
32 Database
33 Visualization means
34 Forecast means
35 Forecast adaptation means
50 Weather station
100 Fault indicators, current sensors
101 Current sensors
102 Gateway, communication module
103 Solar cell
104 Rain gage
105 Temperature sensor
106 Air pressure sensor
107 Wind gage
110 Control center
200 Network
201 Layer
202 Layer
203 Layer
500 Mast
510 Additional communication device
F Fault signal
P Perceptrons
SE Solar radiation values
SE′ Solar radiation values
T Measured temperature values
T′ Measured temperature values
W Weather information
WG Wind speeds
WG′ Wind speeds
WR Wind direction indications
WR′ Wind direction indications

1. A method for operating a fault indicator, which comprises the steps of:
detecting a fault in an electrical energy transmission line;
transmitting a fault signal to a superordinate control center monitoring the electrical energy transmission line in an event of a detected fault; and
transmitting, via the fault indicator regularly or irregularly, at least one item of local weather information relating to weather in an environment of the fault indicator, to the superordinate control center, directly to a central device other than the superordinate control center or indirectly to the central device via the superordinate control center.

2. The method according to claim 1, which further comprises transmitting the at least one item of local weather information using a same communication protocol and on a same communication channel as the fault signal.

3. The method according to claim 1, which further comprises:
storing the at least one item of local weather information in a database of a central cloud system forming the central device or belonging to the central device; and/or
visualizing the at least one item of local weather information, alone or with other weather information from other sources, using visualization means of the central cloud system.

4. The method according to claim 1, which further comprises using the at least one item of local weather information, together with the other weather information from the other sources, to create a weather forecast which, with respect to the environment of the fault indicator, is locally more established, in a manner based on measured values, than a weather forecast without the at least one item of local weather information.

5. The method according to claim 1, which further comprises further processing the at least one item of local weather information during a forecast improvement method, in which a locally modified weather forecast which takes into account the at least one item of local weather information is created on a basis of a previously created global or regional weather forecast and the at least one item of local weather information.

6. The method according to claim 5, wherein the locally modified weather forecast is created and/or the forecast improvement method is carried out using an artificial neural network based on a multilayer perceptron model or related methods.

7. The method according to claim 6, which further comprises:
using the artificial neural network having at least three layers in the forecast improvement method, an input layer and an output layer of the layers of the artificial neural network each having a same number of perceptrons, and each perceptron representing a variable of the locally modified weather forecast for each interval of time;
inputting a previously created global or regional weather forecast and the item of local weather information to the input layer; and
outputting the locally modified weather forecast determined by the neural network by means of the perceptrons of the output layer.

8. The method according to claim 6, wherein before the locally modified weather forecast is created or before the forecast improvement method is carried out, the artificial neural network is trained with an aid of a back propagation method and measured weather information, as training data.

9. The method according to claim 1, which further comprises:
operating the fault indicator or at least a communication module of the fault indicator with solar energy obtained by a solar cell of the fault indicator;
using a respective power output of the solar cell as a measure of respective solar radiation and a measured solar radiation value is generated on a basis of the respective power output; and
transmitting the measured solar radiation value as the at least one item of local weather information or one of the items of local weather information to the superordinate control center and/or the central device.

10. The method according to claim 1, wherein the fault indicator has at least one weather sensor, sensor signals of the weather sensor are transmitted as the item of local weather information to the superordinate control center and/or the central device.

11. The method according to claim 1, wherein:
the fault indicator has a communication module being suitable for transmitting the fault signal to the superordinate control center, and an additional communication device; and
a data connection is maintained between at least one current and/or voltage sensor of the fault indicator and the communication module of the fault indicator and/or the data connection is maintained between at least one external weather sensor and the communication module of the fault indicator by means of the additional communication device.

12. The method according to claim 1, wherein:
in addition to the fault indicator, providing further fault indicators, the further fault indicators:
each monitor a same electrical energy transmission line as the fault indicator or monitor a different electrical energy transmission line of a same energy transmission network which is indirectly or directly connected to the electrical energy transmission line and, in the event of the fault, each transmit a fault signal to the superordinate control center by means of a communication module; and
each regularly or irregularly transmit at least one item of local weather information, which relates to the weather in the environment of a respective fault indicator, directly to the superordinate central device or indirectly to the central device via the control center using the communication module, in each case using a same communication protocol and on a same communication channel as that used to transmit the fault signal from the fault indicator;
if one or more fault signals are received, the superordinate control center determines sections of the electrical energy transmission network which are affected by the fault on a basis of the fault signals; and
the superordinate central device further processes the local weather information from the fault indicators, by performing at least one of:
storing the local weather information in a database of a central cloud system;
visualizing the local weather information;
using the local weather information to create a weather forecast; or
using the local weather information to create a locally modified weather forecast, to be precise on a basis of a previously created global or regional weather forecast and on a basis of the local weather information received by the central device from the fault indicators.

13. The method according to claim 1, wherein:
the fault indicator is a fault current indicator; and
the fault is a fault current in the energy transmission line.

14. The method according to claim 10, which further comprises selecting the at least one weather sensor from the group consisting of a rain gage, a wind gage, a temperature sensor and an air pressure sensor.

15. The method according to claim 11, wherein:
the communication module is a gateway;
the additional communication device is a near field communication device; and
the data connection is in a form of a radio connection.

16. A fault indicator for detecting a fault in an electrical energy transmission line and for transmitting a fault signal to a superordinate control center monitoring the energy transmission line in an event of a detected fault, the fault indicator comprising:
a communication module; and
the fault indicator is configured such that the fault indicator regularly or irregularly transmits at least one item of local weather information, which relates to weather in an environment of the fault indicator, to the superordinate control center, directly to a central device or indirectly to the central device via the superordinate control center using said communication module.

17. The fault indicator according to claim 16,
further comprising at least one weather sensor, sensor signals of said weather sensor being transmitted as the item of local weather information to the superordinate control center and/or the central device; and
wherein the fault indicator is configured for permanently or occasionally having a communication connection to at least one further external weather sensor and forwards received sensor signals from the further external weather sensors to the superordinate control center and/or the central device as the item of local weather information using said communication module.

18. A monitoring device for monitoring an energy transmission network, the monitoring device comprising:
a superordinate control center;
a central device; and
a multiplicity of fault indicators which monitor electrical energy transmission lines of the energy transmission network and each having a communication module, and, in an event of a fault, each of said fault indicators transmitting a fault signal to said superordinate control center using said communication module, said fault indicators are each configured to regularly or irregularly transmit at least one item of local weather information, which relates to weather in an environment of a respective one of said fault indicators, to said superordinate control center, directly to said central device or indirectly to said central device via said superordinate control center using said communication module.
